(19) United States
(12) Patent Application Publication
(10) Pub. No.: US 2014/0353005 A1
(43) Pub. Date: Dec. 4, 2014

(54) METHOD OF MAKING MICROWAVE AND MILLIMETERWAVE ELECTRONIC CIRCUITS BY LASER PATTERNING OF UNFIRED LOW TEMPERATURE CO-FIRED CERAMIC (LTCC) SUBSTRATES

(71) Applicant: E I DU PONT DE NEMOURS AND COMPANY, WILMINGTON, DE (US)

(72) Inventors: DEEPUKUMAR M. NAIR, CARY, NC (US); MICHAEL ARNETT SMITH, WAKE FOREST, NC (US); BRADLEY THRASHER, DURHAM, NC (US); JAMES M. PARISI, STEM, NC (US); ELIZABETH D. HUGHES, RALEIGH, NC (US)

(73) Assignee: E I DU PONT DE NEMOURS AND COMPANY, WILMINGTON, DE (US)

(21) Appl. No.: 14/295,600

(22) Filed: Jun. 4, 2014

Related U.S. Application Data
(60) Provisional application No. 61/830,823, filed on Jun. 4, 2013.

(51) Int. Cl. B05D 3/06; H05K 1/02

(52) U.S. Cl. CPC B05D 3/06; H05K 1/0237
USPC 174/250; 427/554

(57) ABSTRACT

Disclosed are methods of using a laser to pattern unfired, screen printed metallization on unfired (green) LTCC tape material by a subtractive process especially on the internal layers of an LTCC circuit.

### CROSS REFERENCE TO RELATED APPLICATIONS

This is a non-provisional application which claims priority under 35 U.S.C. 119(e) to U.S. Provisional Application No. 61/830,823, filed Jun. 4, 2013. The patent application identified above is incorporated herein by reference in its entirety to provide continuity of disclosure.

### FIELD OF THE INVENTION

Disclosed are methods of patterning unfired, screen printed metallization on unfired (green) LTCC tape material by a subtractive laser process especially on the internal layers of an LTCC circuit.

### BACKGROUND

Low Temperature Co-fired Ceramic (LTCC) technology is an electronic packaging platform especially suitable for high frequency system level packaging applications. A typical LTCC circuit substrate is formed by stacking and laminating multiple layers of ceramic tape (individual layers of which contain conductor patterns formed according to specific circuit design) under pressure and then firing the laminated tape stack up at high temperatures in the range of 800 to 900 degrees Celsius. On firing, LTCC forms a monolithic circuit containing electrical interconnections and provides for a highly reliable integrated circuit chip carrier platform. Electrical interconnections on LTCC substrates are generally formed by using thick film metallizations of gold, silver, or copper metals. Being a ceramic material with no moisture absorption, LTCC is a high reliability system and also has very good thermal properties; 20 times higher thermal conductivity than typical organic laminates, in addition to extremely low dielectric loss for electrical signals. LTCC has a coefficient of thermal expansion (CTE) relatively close to that of semiconductor materials used for fabricating chips thereby making high reliability flip chip attachment possible.

Fabrication of microwave/millimeterwave circuits such as filters, amplifiers, oscillators etc. require very closely spaced conductor traces (line width and spacing of the order of 1 to 2 mil) due to the small wavelengths involved at higher frequencies above 40 GHz. The current state of the art process for thick film metal patterning on the internal layers of LTCC is screen printing, which is an additive process. Current LTCC technology using screen printing is limited to 3 mil line width and line spacing in the best case and hence will not be sufficient for efficient fabrication of microwave and millimeter wave circuits (circuits which operate above a frequency of 40 GHz). Other technologies such as vacuum deposition, electroplating etc. which can be used on the exterior surfaces of LTCC circuits cannot be used on the interior layers since patterning of internal layers is done while the LTCC tape is still in unfired state when the tape material is very soft and in a chemically active state.

### SUMMARY

The current invention discloses a method of patterning unfired, screen printed metallization on unfired (green) LTCC tape material by a subtractive laser process especially on the internal layers of an LTCC circuit.

In a first embodiment, the invention is directed to a method to provide metalized conductor patterns including implementing thick film metallization on interior LTCC tape layers and establishing laser control parameters corresponding to the thick film metallization on interior LTCC tape layers for a laser device. The thick film metallization on interior LTCC tape layers is ablated by the laser device in a defined design pattern having a line width greater than 1 mil, wherein the thick film metallization on interior LTCC tape layers are unfired.

### BRIEF DESCRIPTION OF THE DRAWINGS

FIG. 1 is a photograph illustrating the various gap widths obtained on gold conductor film by using the method of the present invention;

FIG. 2 is a software screen shot illustrating the fiducials of the design;

FIG. 3 is a software screenshot of the parameters for line width;

FIG. 4 is a software screenshot illustrating the design to be ablated with parameters set;

FIG. 5 is a software screenshot of the parameters for the laser;

FIG. 6 is an illustration of the laser and board to be ablated; and

FIG. 7 is a photograph illustrating the substantially smooth edges achieved by the method of the present invention.

### DETAILED DESCRIPTION

In a first embodiment, the invention is directed to a method to provide metalized conductor patterns including implementing thick film metallization on interior LTCC tape layers and establishing laser control parameters corresponding to the thick film metallization on interior LTCC tape layers for a laser device. Unlike present methods in the art, the current invention discloses a method of patterning unfired screen printed metallization on unfired tape material by a subtractive laser process especially on the internal layers of an LTCC circuit. Specifically, the present method includes ablating the thick film metallization on interior LTCC tape layers by a laser device in a defined design pattern producing a line width greater than 1 mil and less than 3 mil. The thick film metallization on interior LTCC tape layers are unfired at the time of ablation. The present invention provides a method to obtain very tight lines and spaces (up to 1 mil resolution), within the multilayer LTCC structure which cannot be fabricated by using standard screen printing techniques. Such high resolution conductor patterns are necessary for fabricating microwave circuits and packages working above 40 GHz frequency. The disclosed process significantly enhances the potential applications for LTCC technology.

The laser device for use in the method, includes an ultraviolet beam having a wavelength in the range of 240-350 nm and a beam spot diameter in range of 15-30 (micrometers). These laser settings provide the parameters to obtain a line width between 1 mil (25.4 microns) and 3 mil (75 microns) by ablation of the metallization upon laser pass. Those skilled in the art would appreciate that the present method would permit greater line width if necessary.

Implementing the thick film metallization on interior LTCC tape layers includes screen printing a block of thick film metallization on LTCC tape layers. The thickness of the thick film is in the range of from 7 to 20 microns extending perpendicular from the tape layers. The physical size of this block print is such that it is much larger than the resolution limit of current screen printing technology (3 mil lines and spaces). Therefore, this block print can be fabricated with screen printing easily without any limitation imposed by the state of the art resolution limit of screen printing. Circuit features requiring higher resolution will be formed by removing metal from areas specified in the design CAD file. Individual metalized LTCC tape layers are loaded into a work area for the laser device for ablating. The laser is not required to “penetrate” the outer layers. Each individual layer is processed separately in un-fired state then stacked up and laminated together followed by firing to form the monolithic circuit. This “subtractive” approach allows the ability to obtain line widths not available by current methods in the art. The ablation permits the resultant metalized tape to be sculpted into a desired pattern which improves the functionality of the device. The defined design pattern is programed in the software which controls the laser device. Such laser systems are available commercially such as model Protolaser U3 or Protolaser U2 ultraviolet available from LPFK Laser and Electronics AG in Garbsen, Germany. The laser may be computer controlled by using custom software available. CAD is the primary software to direct the laser and is commercially available. The CAD program can be a generic drawing software such as AutoCAD, or SolidWorks.

The tape layers are low loss glass ceramic dielectric tape for high frequency applications. Most commonly, DuPont GreenTape™ LTCC 9K7 and 9K5 LTCC materials systems are used. The thick film metallization material includes gold, silver, and copper thick film metallization and combinations thereof. One skilled in the art would appreciate the combination of tape and metal are core to defining the parameters of the laser. The laser parameters need to be optimized for the specific combination of tape (i.e. the dielectric) and metal used. One skilled in the art would appreciate the need for this optimization and recognize the parameters used for typical organic printed circuit boards “PCBs” (PTFE, FR-4 etc.) with copper metallization would not be used for ceramic and thick film metal pastes.

The specified laser parameters are established after several trail runs and experiments. These parameters are developed by a series of process experiments to obtain appropriate values. More specifically, a “test coupon” is created to recognize the interrelationship between the parameters and the specific design “measurements” or gap width to be achieved. Specifically, for this purpose, the test coupon is fabricated under various process set points and measured performance parameters, such as insertion loss of the transmission lines, return loss of the transmission lines, geometric definition of the lines, (using Scanning Electron Microscope (SEM) micrographs), the gap space between conductors, the depth of “cut” in to the unfired LTCC sheet etc., e.g. trials on the test coupon define the parameters to obtain the desired results. This provides evidence that the particular parameters as defined are critical, and illustrate that the claimed parameters are required to obtain the desired design antenna “measurements” and gap width.

### EXAMPLES

### Example 1

Table 1 provides the ranges for a 340 nm UV laser using thickgold metallization materials formed on DuPont GreenTape™ LTCC 9K7.

TABLE 1

| Laser Parameter (units) | Value |
|---|---|
| Pulse repetition frequency (KHz) | 100-150 |
| Laser Power (W) | 2-7 |
| Jump delay (micro seconds) | 1000-3000 |
| Jump speed (mm/s) | 500-1500 |
| Laser off delay (micro second) | 50-200 |
| Laser on delay (micro second) | 0-10 |
| Mark delay (micro second/s) | 400-800 |
| Mark speed (mm/s) | 100-500 |
| Polygon delay (micro second) | 0-10 |
| Air Pressure | NO |
| Repetition | 1-3 |
| Tool delay (milli second) | 0-10 |
| Tool Z - offset (um) | 0-10 |

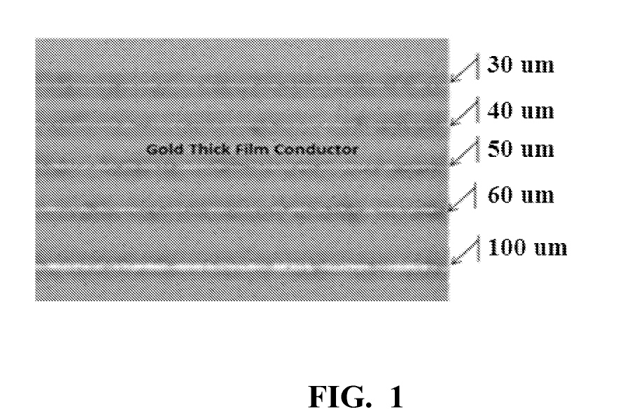

The capability of this laser ablation process to achieve line width of 1 mil (25.4 micron) is illustrated. The set of parameters in Table 1 can provide line width as narrow as 1 mil. However, depending upon the size of the lines specified in the design CAD the same parameters can be used for broader lines. The parameters are also optimized for minimizing the amount of the dielectric substrate material (LTCC in this case) that will be removed during ablation. Since this is fundamentally a mechanical removal of materials there is always some chance of dielectric material getting removed along with the metal (which is undesired). The purpose of optimization of the parameters is to make sure all of the metal is removed without removing any dielectric substrate materials. FIG. 1 illustrates varied gap widths of 30, 40, 50, 60 and 100 microns ablated on a “gold metallization” tape by the present invention. The method provides the ability to obtain a millimeter wave (MMW) structure having a frequency above 40 GHz. Providing gap widths of between 1 and 3 microns allows an MMW structure to operate at small wavelengths involved at higher frequencies above 40 GHz.

### Example 2

As discussed, circuit fabrication using the laser ablation process on LTCC has four steps after completing the desired design; 1) import the design file to the CAD program used by the laser (Circuit CAM), 2) prepare and export the file to laser control software Circuit Master, 3) set laser parameters and align the work piece, 4) laser ablation. Details of these steps are described below.

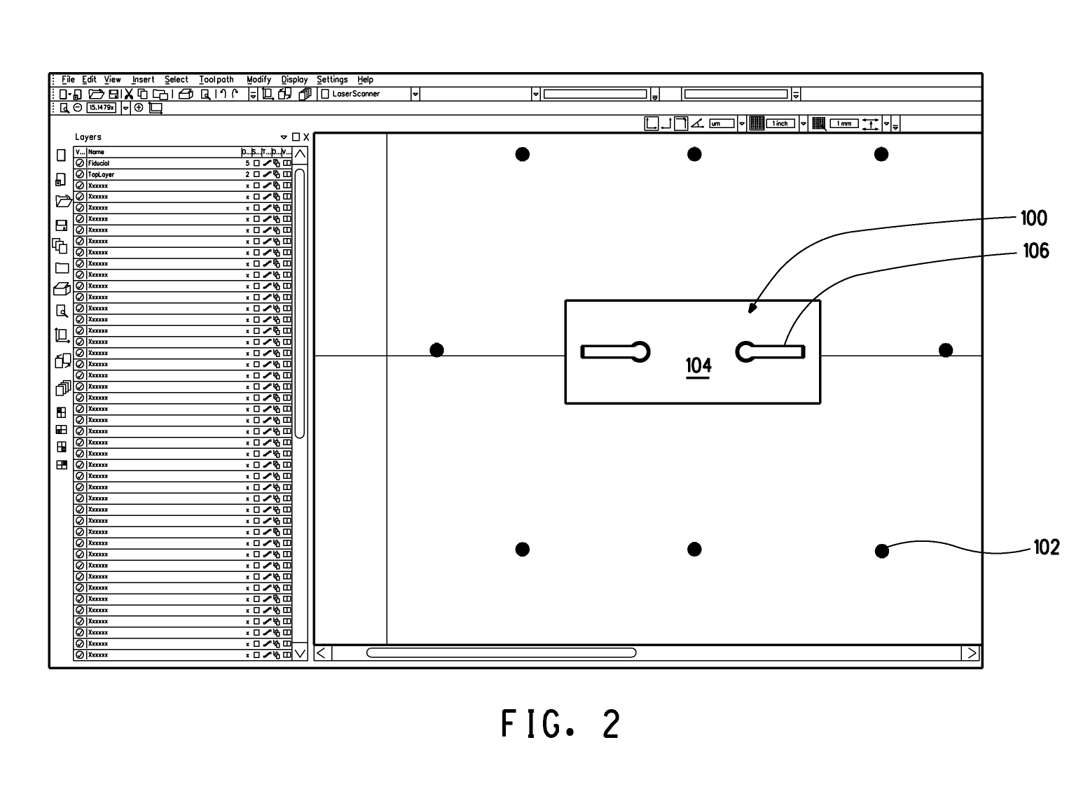

Referring to FIGS. 2-4, the initial step is to import the design file 100 into CircuitCAM and highlight the alignment fudicials 102 using the software. The next step is to highlight the areas to be laser ablated and identify them as TopLayer 104.

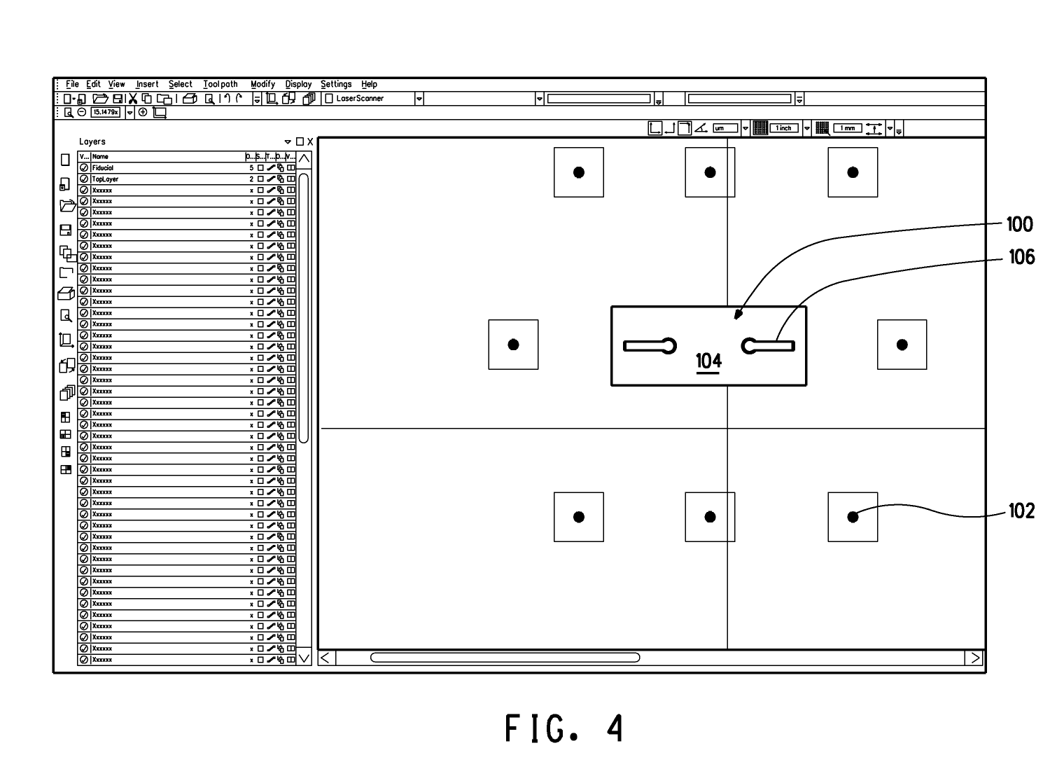

After the areas to be ablated are highlighted, hatching (e.g. laser path) or “contour lines” 106 are created in the areas to be laser ablated with each hatch line 106 representing a laser “pass”. These lines 106 follow the geometry to be ablated as specified by the design file 100. FIG. 4 illustrates highlighted area for ablation as designated by the design file.

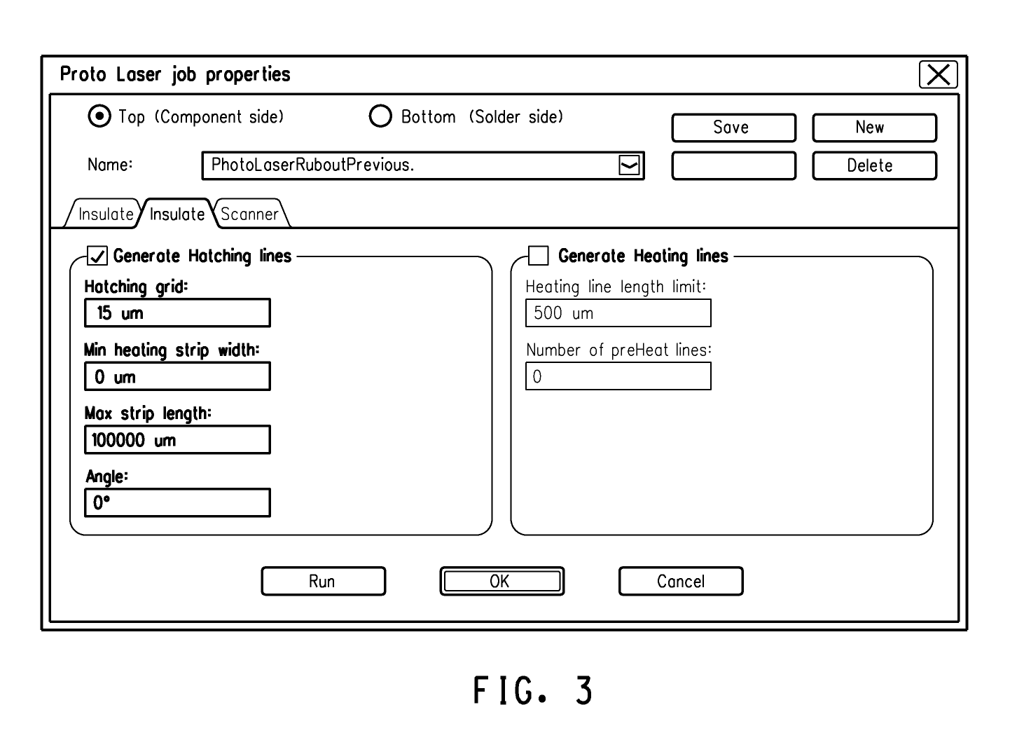

Referring to FIG. 3, the laser paths (laser beam width) are 25 um wide and the hatching grid must be set to 15 um to provide a 10 um overlap of the laser beam to ensure all material is removed or ablated. The “overlap” is the external areas of the contour lines 106 which will be ablated by the laser pass. The setting for the laser beam width and hatch width are not used to control line width but as an effective method to ensure the laser beam ablates effectively; this is important for LTCC green sheet processing. The contour line 106 that the laser will use will define the edges (as discussed herein). At this point the file is ready to be exported to CircuitMaster.

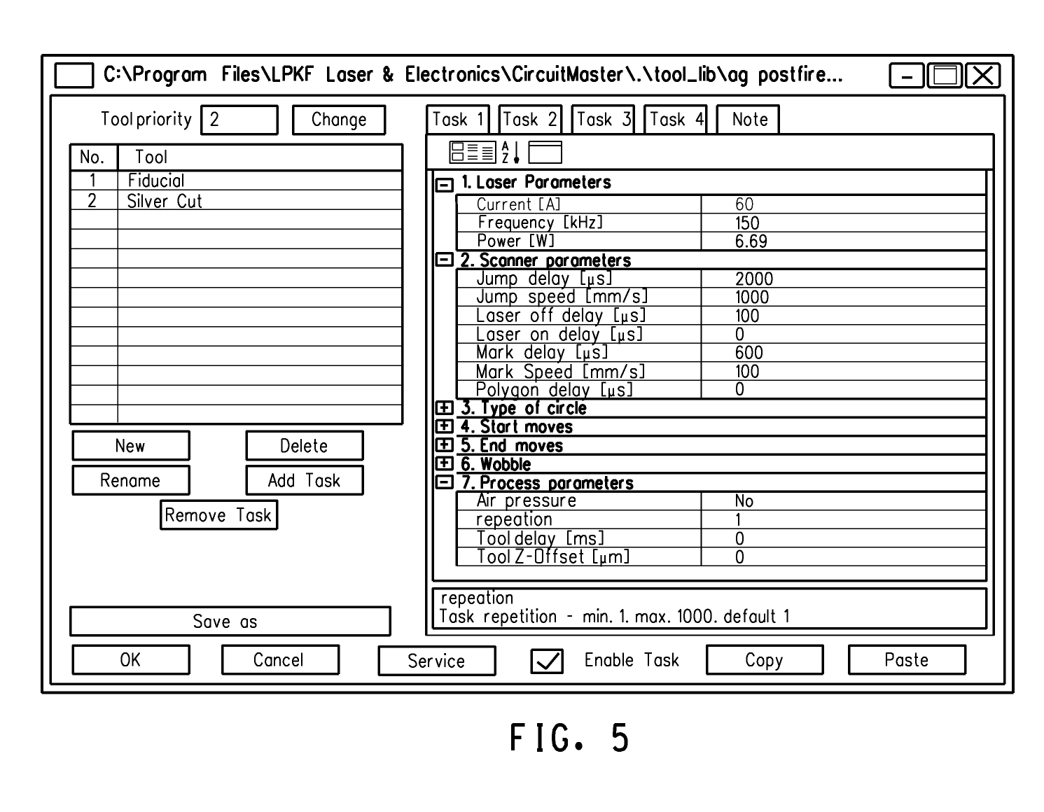

Referring to FIG. 5, once the file is imported into CircuitMaster, the necessary tools are assigned for hatching, contour and fiducials, e.g. marks for specific geometric shapes used to align substrates to laser a coordinate system. The tool library is opened and the parameters are set for the conductor material being processed. An example of a tool setup for a LTCC green sheet printed with Ag conductor is illustrated in FIG. 5, however, the Mark Speed (mm/s) used can be in the range of 100 to 200 mm/s depending on the type of conductor that is being ablated. The rest of the parameters shown are not changed.

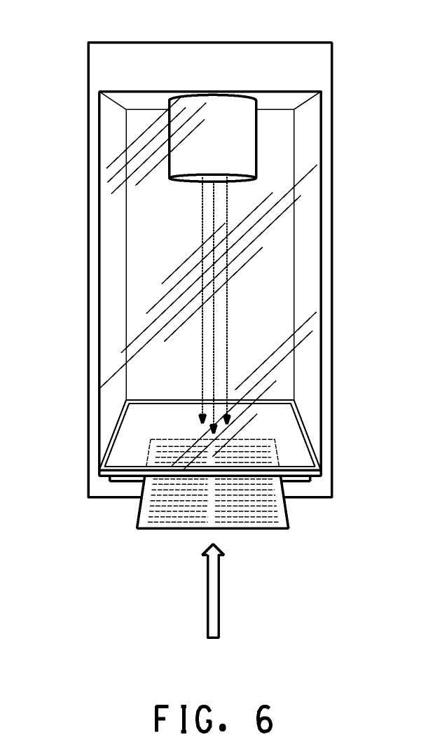

The last step is to place the LTCC green sheet in the laser, line up the laser crosshair with the area to be laser ablated and start the laser ablation process. As best illustrated in FIG. 6, the laser removes the metal to form patterns. Example 2 provides specific process and parameters to provide a conductor line of as narrow as 25 microns, wherein the resulting EBG structures can function up to 100 GHz.

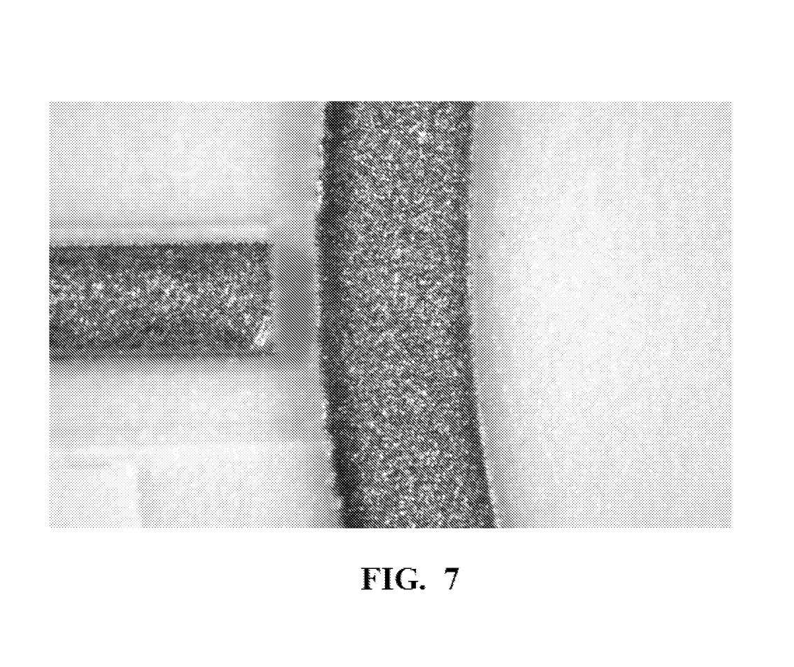

As illustrated in FIG. 7, the process of the present invention provides clearly defined edges of the metalization. The process of the present invention provides a substantially planar resultant edge of metallization having less than five percent (5%) outward or inward protrusions, based on the width of the metallization after ablation, from the planar surface of the edge. Signal loss is a function of the degree of the edge smoothness of the conductors. The ability of the method of the present invention to provide a substantially smooth conductor edge resulting in a reduction of signal loss is a desired advantage in the industry.

What is claimed is:

1. A method to provide metalized conductor patterns comprising:
a. forming thick film metallization on an LTCC tape layer;
b. establishing laser control parameters corresponding to the thick film metallization on the LTCC tape layers for a laser device;
c. ablating the thick film metallization on the LTCC tape layers by the laser device in a defined design pattern on the thick film metallization on LTCC tape layers of a line width greater than 1 mil,
wherein the thick film metallization on the LTCC tape layers is unfired.

2. The method of claim 1, wherein the laser comprises an ultraviolet beam having a wavelength in the range of 240-350 nm and a beam spot diameter in range of 15-30 microns.

3. The method of claim 2, wherein the line width is between 1 mil and 3 mil.

4. The method of claim 3, wherein implementing the thick film metallization on interior LTCC tape layers comprises screen printing a block of thick film metallization on LTCC tape layers, wherein the LTCC tape layers are loaded into a work area for the laser device for ablating.

5. The method of claim 4 wherein the defined design pattern is provided by a software program which controls the laser device.

6. The method of claim 5, wherein the LTCC tape layers are low loss glass ceramic dielectric tape for high frequency applications.

7. The method of claim 6, wherein the thick film metalization comprise gold, silver, and copper thick film metalization and combinations thereof.

8. The method of claim 7, wherein process of the present invention provides a substantially planar resultant edge of metallization having less than five percent (5%) outward or inward protrusions, based on the width of the metallization after ablation, from the planar surface of the edge.

9. The method of claim 8, wherein ranges for the laser control parameters are established based on a disired outcome of line width and frequency of a millimeter wave structure.

10. The method of claim 8, wherein ranges for the laser control parameters comprise:
(i) Pulse repetition frequency of 100-150 kilohertz (KHz);
(ii) Laser Power of 2-7 Watts;
(iii) Jump delay of 1000-3000 micro seconds;
(iv) Jump speed of 500-1500 mm/s;
(v) Laser off delay of 50-200 micro second;
(vi) Laser on delay 0-10 micro second;
(vii) Mark delay of 400-800 micro second/s;
(viii) Mark speed 100-500 mm/s;
(ix) Polygon delay 0-10 micro second;
(x) Air Pressure about 0;
(xi) Repetition between 1 and 3 passes of the unltraviolet beam of the laser;
(xii) Tool delay 0-10 millisecond, and
(xiii) Tool Z—offset 0-10 um.11.

11. A millimeter wave structure having a frequency above 50 GHz made by the method of claim 9 or 10.
